(19) United States
(12) Patent Application Publication
(10) Pub. No.: US 2021/0044303 A1
(43) Pub. Date: Feb. 11, 2021

(54) NEURAL NETWORK ACCELERATION DEVICE AND METHOD

(71) Applicant: SZ DJI TECHNOLOGY CO., LTD., Shenzhen (CN)

(72) Inventors: Feng HAN, Shenzhen (CN); Qian GU, Shenzhen (CN); Sijin LI, Shenzhen (CN)

(21) Appl. No.: 17/080,138

(22) Filed: Oct. 26, 2020

Related U.S. Application Data
(63) Continuation of application No. PCT/CN2018/084704, filed on Apr. 26, 2018.

(51) Int. Cl. H03M 7/24; G06F 17/15; G06N 3/04

(52) U.S. Cl. CPC H03M 7/24; G06N 3/04; G06F 17/15

(57) ABSTRACT

A neural network acceleration device includes a processor and a storage medium. The storage medium stores instructions that, when executed by the processor, cause the processor to obtain an input feature value, perform computation processing on the input feature value to obtain an output feature value, and in response to a fixed-point format of the output feature value being different from a predetermined fixed-point format, perform at least one of a low bit shifting operation or a high bit truncation operation on the output feature value according to the predetermined fixed-point format to obtain a target output feature value. A fixed-point format of the target output feature value is the predetermined fixed-point format.

### CROSS-REFERENCE TO RELATED APPLICATION

This application is a continuation of International Application No. PCT/CN2018/084704, filed Apr. 26, 2018, the entire content of which is incorporated herein by reference.

### TECHNICAL FIELD

The present disclosure generally relates to the neural network field and, more particularly, to a neural network acceleration device and method.

### BACKGROUND

An existing main neural network computing frame mainly uses a floating-point number to perform training and computation. For example, a weight coefficient obtained after the neural network computing frame is trained and an output feature value of each of the layers are single-precision or double-precision floating-point numbers. Since a fixed-point computing device occupies a smaller area and consumes less power compared to a floating-point computing device, neural network acceleration devices commonly use the fixed-point number as a data format required by a computation unit. Therefore, a fixed-point conversion needs to be performed on the weight coefficient obtained after the neural network computing frame is trained and the output feature value of each of the layers when they are deployed in the neural network acceleration device. Fixed-point conversion refers to a process of converting data from a floating-point number to a fixed-point number.

In the existing technology, fixed-point conversion of the weight coefficient is usually performed by a configuration tool before the network is deployed, and fixed-point conversion of an input feature value (or output feature value) is usually performed by a central processing unit (CPU) during the process of the neural network computation. In addition, different data (the input feature value or the output feature value) of the same layer and same data (the input feature value or the output feature value) of different layers may have different fixed-point format after the fixed-point conversion. Therefore, the fixed-point format of the data needs to be adjusted. In the existing technology, the CPU is configured to adjust the fixed-point format of the data.

In a process of the neural network computation, the flow of data interaction between the CPU and the neural network acceleration device includes that 1) the neural network acceleration device writes the processed data into a double data rate (DDR) storage device, 2) the CPU reads the data to be processed from the DDR, 3) the CPU writes a data processing result into the DDR, and 4) the neural network acceleration device obtains the result after the data is processed by the CPU from the DDR.

The above CPU data processing solution needs a long time, which reduces the efficiency of the neural network data computation.

### SUMMARY

Embodiments of the present disclosure provide a neural network acceleration device including a processor and a storage medium. The storage medium stores instructions that, when executed by the processor, cause the processor to obtain an input feature value, perform computation processing on the input feature value to obtain an output feature value, and in response to a fixed-point format of the output feature value being different from a predetermined fixed-point format, perform at least one of a low bit shifting operation or a high bit truncation operation on the output feature value according to the predetermined fixed-point format to obtain a target output feature value. A fixed-point format of the target output feature value is the predetermined fixed-point format.

Embodiments of the present disclosure provide a neural network data processing method. The method includes obtaining an input feature value, performing computation processing on the input feature value to obtain an output feature value, and in response to a fixed-point format of the output feature value being different from a predetermined fixed-point format, performing at least one of a low bit shifting operation or a high bit truncation operation on the output feature value according to the predetermined fixed-point format to obtain a target output feature value. A fixed-point format of the target output feature value is the predetermined fixed-point format.

### BRIEF DESCRIPTION OF THE DRAWINGS

FIG. 1 is a schematic frame diagram of a deep convolutional neural network.

FIG. 2 is a schematic architectural diagram of a neural network acceleration device according to some embodiments of the present disclosure.

FIG. 3 is a schematic block diagram of the neural network acceleration device according to some embodiments of the present disclosure.

FIG. 4 is a schematic flowchart showing an output circuit of the neural network acceleration device processing an output feature value according to some embodiments of the present disclosure.

FIG. 5 is a schematic flowchart showing an input circuit of the neural network acceleration device processing an input feature value according to some embodiments of the present disclosure.

FIG. 6 is a schematic flowchart showing a data processing method used in the neural network according to some embodiments of the present disclosure.

### DETAILED DESCRIPTION OF THE EMBODIMENTS

The technical solution of embodiments of the present disclosure is described in connection with the accompanying drawings.

Unless otherwise specified, all technical terms and scientific terms used in the present disclosure have same meanings as commonly understood by those skilled in the art of the present disclosure. The terms used in the description of the present disclosure are only for the purpose of describing specific embodiments and are not intended to limit the present disclosure.

Technologies and principles related to embodiments of the present disclosure are described first.

1. Neural Network (e.g., Deep Convolutional Neural Network (DCNN))

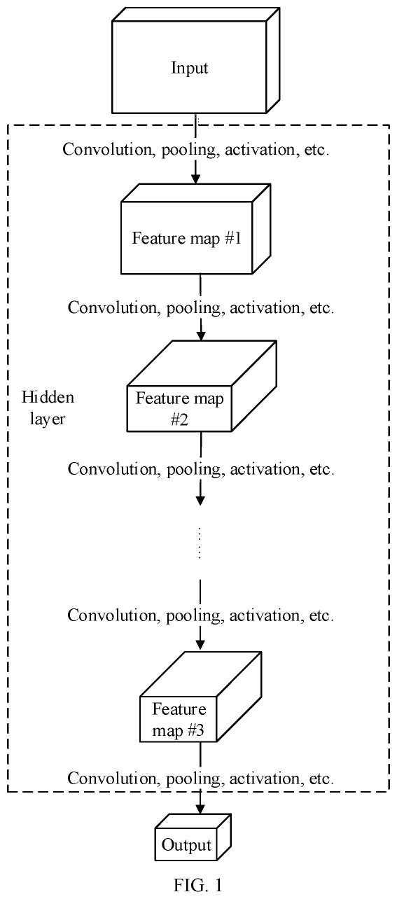

FIG. 1 is a schematic frame diagram of the deep convolutional neural network. An output value (output by an output layer) is obtained after a hidden layer performing computations, such as convolution, transposed convolution or deconvolution, batch normalization (BN), scale, fully connected, concatenation, pooling, element-wise addition, activation, etc., on an input value (input by an input layer) of the deep convolutional neural network. In embodiments of the present disclosure, a possible computation related to the hidden layer of the neural network is not limited to the above-described computations.

The hidden layer of the deep convolutional neural network may include a plurality of cascaded layers. An input of each layer may be an output of an upper layer and may be a feature map. Each layer may perform at least one of the above computations on one or more input feature maps to obtain an output of the layer. The output of each layer may also be a feature map. In general, each layer may be named after a function that is realized, for example, the layer for implementing the convolutional computation may be referred to as a convolutional layer. In addition, the hidden layer may further include a transposed convolutional layer, a BN layer, a scale layer, a pooling layer, a fully connected layer, a concatenation layer, an element-wise addition layer, an activation layer, etc., which are not listed here one by one.

Each of the above-described layers (including the input layer and the output layer) may include an input and/or an output, or a plurality of inputs and/or a plurality of outputs. In classification and detection tasks of the visual field, a width and a height of the feature map tend to decrease layer by layer (e.g., as shown in FIG. 1, the width and height of the input, feature map #1, feature map #2, feature map #3, and output decrease layer by layer). In a semantic dividing task, after the width and height of the feature map decrease to a certain degree, the width and height of the feature map may increase layer by layer through the transposed convolutional computation or upsampling computation.

In general, an activation layer may follow the convolutional layer. The activation layer may include a rectified linear unit (ReLU) layer, a sigmoid layer, a tanh layer, etc. After the BN layer was proposed, more and more neural networks may first perform a BN process after the convolution, and then perform the activation computation.

The layers that require relatively more weight parameters for computation may include the convolutional layer, the fully connected layer, the transposed convolutional layer, and the BN layer.

2. Fixed-Point Number

The fixed-point number is represented by a sign bit, an integer part, and a decimal part.

bw denotes a total bit-width (TW) of the fixed-point number, s denotes the sign bit (usually the very left bit of the number), fl denotes a bit-width of the decimal part, and xᵢ denotes a value of each of the bits (also called mantissa bits). A real value of a fixed-point number may be represented by:

$$x = {( - 1 )}^{s} \times {2}^{- fl} \times {\sum }_{i = 0}^{b w - 2} {2}^{i} \times {x}_{i} .$$

For example, a fixed-point number may be 01000101, the bit-width is 8 bits, the highest bit (0) is the sign bit, the bit-width fl of the decimal part is 3. Therefore, the real value represented by the fixed-point number is:

x=(−1)⁰×2⁻³×(2⁰+2²+2⁶)=8.625.

A format of the fixed-point number may be simplified as m.n, where m denotes a bit number of effective data, and n denotes a bit number of the decimal part of the effective data. The TW of the data is m+1. In some embodiments, the first bit may be the sign bit.

For example, the fixed-point format of data may be 7.2, which may indicate that the bit number of the effective data of the data is 7, the bit number of the decimal part in the effective data is 2, and the bit-width of the data is 8.

An expression of the fixed-point number with the sign bit is described above. The fixed-point number may also not have the sign bit. For example, a fixed-point number may be 01000101, the bit-width is 8, the effective bits number is also 8, the bit-width of the decimal part is 3, thus, the fixed-point format of the fixed-point number is represented as 8.3.

The solution of embodiments of the present disclosure may be suitable for a scenario of the fixed-point number with the sign bit and also for a scenario of the fixed-point number without the sign bit, which is not limited by embodiments of the present disclosure. However, to facilitate understanding and description, embodiments blow mainly use examples of the scenario of the fixed-point number with the sign bit for description. The described solution may be applicable to the scenario of the fixed-point number without the sign bit through an appropriate conversion, and the solution is within the scope of the present disclosure.

Different data of the same layer and the same data of different layers in the neural network may have different fixed-point formats after fixed-point conversion. For example, data 1 and data 2 of the same layer may have a fixed-point format of 7.2 (the bit number of the effective data is 7, and the bit number of the decimal part is 2) and a fixed-point format of 7.4 (the bit number of the effective data is 7, and the bit number of the decimal part is 4), respectively. The fixed-point format of the input feature value after fixed-point conversion may be different from the data format required by the computation unit of the neural network acceleration device. For example, the fixed-point format of the input feature value may be 7.2 (the bit number of the effective data is 7, and the bit number of the decimal part is 2). The bit-width of the input and output required by the computation unit is 16 bits. The fixed-point format of the output feature value of the computation unit of the neural network acceleration device may be different from a predetermined fixed-point format. Therefore, in a network computation process, in addition to converting the data of the floating-point format to the data of the fixed-point format, the fixed-point format of the data with the fixed-point format may need to be adaptively adjusted.

In some embodiments, the CPU may be configured to perform an adaptive adjustment on the fixed-point format of the data with the fixed-point format. According to the above description, the CPU and the neural network acceleration device may exchange data with each other through the DDR. Such a method may reduce the data processing speed and increase the consumption of a DDR bandwidth.

Embodiments of the present disclosure provide a neural network acceleration device and method, which may effectively increase the efficiency of the neural network data processing.

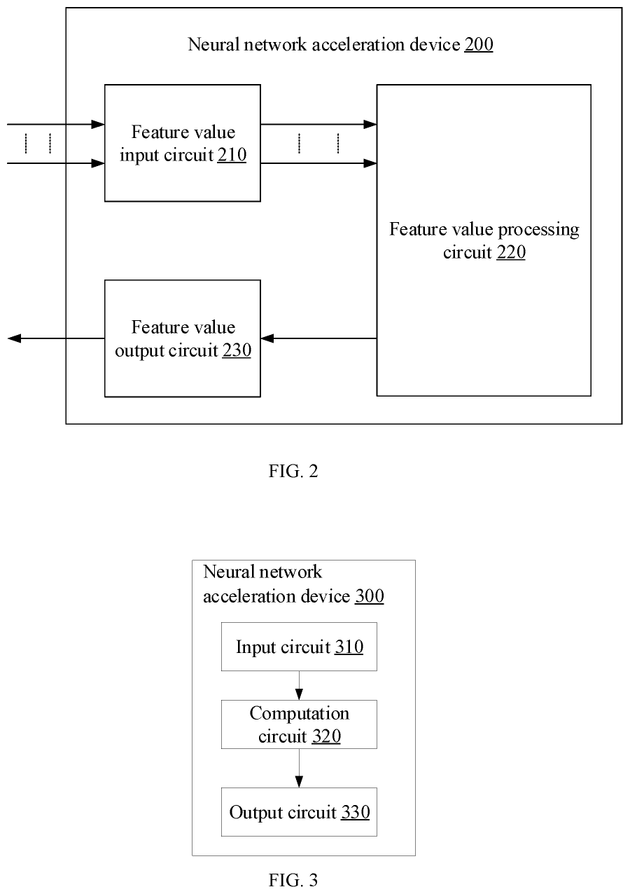

FIG. 2 is a schematic architectural diagram of a neural network acceleration device 200 according to some embodiments of the present disclosure. The device 200 includes a feature value input circuit 210, a feature value processing circuit 220, and a feature value output circuit 230.

The feature value input circuit 210 may be configured to obtain the input feature value and transmit the obtained input feature value to the feature value processing circuit 220 for processing.

For example, the input feature value obtained by the feature value input circuit 210 may include the data of the input feature map of the whole neural network. A fixed-point conversion may be performed on the input feature value map before the feature value map is deployed in the neural network. That is, the data format of the input feature value obtained by the feature input circuit 210 may be the fixed-point number.

As another example, the input feature value obtained by the feature value input circuit 210 may be the input feature value of a current layer of the neural network. The input feature value may be the output feature value of an upper layer. Since the neural network acceleration device may use the fixed-point number as the data format required by the computation unit, the output feature value of the upper layer may also be the data of the fixed-point format. That is, the data format of the input feature value obtained by the feature value input circuit 210 may be the fixed-point number.

In embodiments of the present disclosure, the input feature value obtained by the feature value input circuit 210 may be the data of the fixed-point format.

As shown in FIG. 2, the feature value input circuit 210 obtains a plurality of input feature values simultaneously.

In some embodiments, the feature value input circuit 210 may be further configured to, before the feature value is transmitted to the feature value processing circuit 220, perform a bit-width extension operation and/or shifting operation on the input feature value. The bit-width extension operation may refer to an extension of the total bit number of the input feature value. For example, the input feature value may include 8 bits initially, which may be extended to 16 bits. The shifting operation may include a left shifting operation or a right shifting operation. The bit-width extension operation and the shifting operation are described below.

The feature value processing circuit 220 may be configured to perform the computation processing on the input feature value received by the feature value input circuit 210.

For example, the computation processing of the input feature value by the feature value process circuit 220 may include but is not limited to convolutional processing by the convolutional layer, pooling layer processing, element-wise processing by the element-wise layer, etc. For a multi-element variable such as a vector or a matrix, the element-wise operation may refer to the computation thereof being performed on each of the elements. That is, if the element-wise operation is an addition operation, a certain value may be added to each element.

The feature value process circuit 220 may use the fixed-point number as the data format for the computation processing, that is, the data format of the computation operating number in the feature value processing circuit 220 may be the fixed-point number.

The feature value output circuit 230 may be configured to receive the output feature value obtained by the feature value processing circuit 220 and process the output feature value as the data of the predetermined fixed-point format.

Since the feature value processing circuit 220 may use the fixed-point number as the data format for the computation processing, the data format of the output feature value obtained by the feature value processing circuit 220 may be the fixed-point number. That is, the data format of the output feature value received by the feature value output circuit 230 may be the fixed-point number.

For example, the output feature value of the predetermined fixed-point format obtained by the feature value output circuit 230 may be output to a next layer and used as an input feature value of the next layer. As another example, the output feature value of the predetermined fixed-point format obtained by the feature value output circuit 230 may be used as an output result of the whole network.

The predetermined fixed-point format of the present disclosure may be preconfigured. For example, the predetermined fixed-point format may be configured by a configuration program via a register.

The neural network acceleration device provided by embodiments of the present disclosure may not only perform the computation processing on the data but also perform the adaptive adjustment on the fixed-point format of the data. Since no CPU needs to perform the adjustment on the fixed-point format of the data, a number of the data exchanges between the DDR and the CPU may be reduced to a certain degree. Therefore, the neural network data processing may be sped up, the usage of the DDR may be lowered, and the resource consumption may be reduced.

In embodiments of the present disclosure, processing the input feature value and/or the output feature value may be considered as a fixed-point conversion method for converting a fixed-point format into another fixed-point format.

FIG. 3 is a schematic block diagram of a neural network acceleration device 300 according to some embodiments of the present disclosure.

The device 300 includes an input circuit 310 configured to obtain an input feature value.

The data format of the input feature value obtained by the input circuit 310 may be a fixed-point number.

In some embodiments, the input feature value obtained by the input circuit 310 may be the data of the input feature map of the whole neural network.

The input feature value map may be converted into the fixed-point format before deployed in the neural network. That is, the data format of the input feature value obtained by the input circuit 310 may be the fixed-point number.

In some embodiments, the input feature value obtained by the input circuit 310 may be the input feature value of the current layer (i.e., the layer that is currently performing the computation processing) in the neural network. The input feature value is the output feature value of the upper layer.

Since the neural network acceleration device may use the fixed-point number as the data format required by the computation unit, the output feature value of the upper layer may also be the data of the fixed-point format. That is, the data format of the input feature value obtained by the input circuit 310 may be a fixed-point number.

In some embodiments, the input circuit 310 may obtain one or more input feature values.

The input circuit 310 corresponds to the feature value input circuit 210 of above embodiments.

The device 300 further includes a computation circuit 320 configured to perform the computation processing on the input feature value received by the input circuit 310 to obtain the output feature value.

In some embodiments, the computation processing of the input feature value by the computation circuit 320 may include but is not limited to one of the computations, such as the convolutional processing by the convolutional layer, the pooling layer processing, the element-wise operation by the element-wise layer, etc.

The computation circuit 320 may correspond to the feature value processing circuit 220 of above embodiments.

The device 300 further includes an output circuit 330 configured to, when the fixed-point format of the output feature value obtained by the computation circuit 320 is different from the predetermined fixed-point format, perform low bit shifting operation and/or high bit truncation operation on the output feature value according to the predetermined fixed-point format to obtain a target output feature value. The fixed-point format of the target output feature value may be the predetermined fixed-point format.

In some embodiments, the fixed-point format is represented as m.n, where m denotes the bit number of the effective data, and n denotes the bit number of the decimal part of the effective data.

Assume the predetermined fixed-point format is 7.2. For example, the fixed-point format of the output feature value obtained by the computation circuit 320 may be 7.4, thus, the low bit shifting operation needs to be performed on the output feature value to obtain the target output feature value having the fixed-point format of 7.2. As another example, the fixed-point format of the output feature value obtained by the computation circuit 320 may be 15.2, thus, the high bit truncation operation needs to be performed on the output feature value to obtain the target output feature value having the fixed-point format of 7.2. As another example, the fixed-point format of the output feature value obtained by the computation circuit 320 may be 15.4, thus, the low bit shifting operation and high bit truncation operation need to be performed on the output feature value to obtain the target output feature value having the fixed-point format of 7.2.

The output circuit 320 may correspond to the feature value output circuit 230 of above embodiments.

In embodiments of the present disclosure, the fixed-point format of the data may be adjusted by the neural network acceleration device. Since CPU may not be needed to perform the adjustment on the fixed-point format of the data, the number of data exchanges between the DDR and the CPU may be reduced to a certain degree. Therefore, the neural network data processing speed may be accelerated to a certain degree to improve the neural network data processing efficiency.

In embodiments of the present disclosure, the neural network acceleration device may perform the adjustment on the fixed-point format of the data. Since CPU may not be needed to perform the adjustment on the fixed-point format of the data, the usage of the DDR may be reduced to a certain degree, and the resource consumption may be reduced.

In some embodiments, the bit number of the decimal part represented by the fixed-point format of the output feature value output by the computation circuit 320 may be larger than the bit number of the decimal part of the predetermined fixed-point format. In this scenario, the output circuit 330 may need to perform the low bit shifting operation on the output feature value. The output circuit 330 may be configured to shift away L low bits of the output feature value according to the predetermined fixed-point format. L is equal to a difference obtained by the bit number of the decimal part represented by the fixed-point format of the output feature value output by the computation circuit 320 minus the bit number of the decimal part represented by the predetermined fixed-point format. When the value represented by the L low bits is larger than or equal to half of the largest value that can be represented by L bits, the output feature value having the L low bits shifted out may be added by 1 to obtain the target output feature value. When the value represented by the L low bits is smaller than half of the largest value that can be represented by L bits, the output feature value having the L low bits shifted out may be used as the target output feature value.

In some embodiments, the value of the L bits shifted out of the output feature value may be compared to the largest value that can be represented by L bits to determine whether to add 1 to the processed output feature value. This process is referred to as rounding up and down.

In some embodiments, when the value represented by the L low bits is larger than or equal to the half of the largest value that can be represented by L bits, rounding up may be performed, otherwise rounding down may be performed. However, the present disclosure does not limit this. In practical applications, a determination criterion for the rounding up and down may be set according to the actual needs. For example, when the value represented by the L low bits is larger than or equal to 65% of the largest value that can be represented by L bits, rounding up may be performed, otherwise rounding down may be performed. As another example, when the value represented by the L low bits is larger than or equal to 95% of the largest value that can be represented by L bits, rounding up may be performed, otherwise, rounding down may be performed.

In embodiments of the present disclosure, after the low bit shifting operation is performed on the output feature value, the rounding up and down operation may be performed on the processed output feature value. As such, an accuracy loss of the output feature value of the final output may be ensured to be small to a certain degree.

When the bit number of the decimal part represented by the fixed-point format of the output feature value output by the computation circuit 320 is equal to the bit number of the decimal part represented by the predetermined fixed-point format, the output circuit 330 may not need to perform the low bit shifting operation on the output feature value.

When the bit number of the decimal part represented by the fixed-point format of the output feature value output by the computation circuit 320 is smaller than the bit number of the decimal part represented by the predetermined fixed-point format, the output circuit 330 may directly add 0 to a low bit of the output feature value.

In some embodiments, when the effective bits represented by the fixed-point format of the output feature value output by the computation circuit 320 is larger than the effective bits represented by the predetermined fixed-point format, the output circuit 330 may need to perform the high bit truncation operation on the output feature value to cause the bit number of the effective data after the high bit truncation operation to be equal to the effective bit number represented by the predetermined fixed-point format.

In a first scenario, if the low bit shifting operation and rounding up and down operation are performed on the output feature value output by the computation circuit 320, the high bit truncation operation may be performed based on the process result of the rounding up and down.

In a second scenario, if the low bit shifting operation and rounding up and down operations are not performed on the output feature value output by the computation circuit 320, the high bit truncation operation may be directly performed on the output feature value output by the computation circuit 320.

When the output feature value after the low bit shifting operation, rounding up and down operation, and/or high bit truncation operation is larger than the largest value represented by the predetermined fixed-point format or smaller than the smallest value represented by the predetermined fixed-point format, the output circuit 330 may need to perform saturation processing on the output feature value.

In some embodiments, the output feature value may be larger than the largest value represented by the predetermined fixed-point format. The output circuit 330 may be further configured to use the largest value represented by the predetermined fixed-point format as the target output feature value.

For example, when the bit number of the effective data of the fixed-point number having the sign bit represented by the predetermined fixed-point format is mi, the bit number of the decimal part of the effective data may be n₁. The target output feature value may be larger than the largest value represented by m₁+1 bits. The output circuit 330 may be configured to use the largest positive value represented by the m₁+1 bits as the target output feature value.

As another example, when the bit number of the effective data of the fixed-point number without the sign bit represented by the predetermined fixed-point format is m₃, the bit number of the decimal part of the effective number may be n₃. The target output feature value may be larger than the largest value represented by m₃ bits. The output circuit 330 may be configured to use the largest positive value represented by the m₃ bits as the target output feature value.

In some embodiments, the output feature value may be larger than the smallest value represented by the predetermined fixed-point format. The output circuit 330 may be further configured to use the smallest value represented by the predetermined fixed-point format as the target output feature value.

For example, the bit number of the effective data of the fixed-point number having the sign bit represented by the predetermined fixed-point format may be m₂, the bit number of the decimal part of the effective number may be n₂. The target output feature value may be smaller than the smallest negative value represented by m₂+1 bits. The output circuit 330 may be configured to use the smallest negative value represented by the m₂+1 bits as the target output feature value.

In some embodiments, the object of the saturation processing may be the output feature value output by the computation circuit 320, or a result after the low bit shifting operation and rounding up and down operation may be performed on the output feature value output by the computation circuit 320, or a result after the high bit truncation operation may be performed on the output feature vale output by the computation circuit 320, or a result after the low bit shifting operation, the rounding down and up, and the high bit truncation operation may be performed on the output feature value output by the computation circuit 320.

With the high bit truncation operation on the output feature value, the TW of the output feature value may be the same as the TW represented by the predetermined fixed-point format.

To better understand the solution of the present disclosure, the following examples are used to describe the processing method of the output circuit 330 to the output feature value output by the computation circuit 320.

Assume the predetermined fixed-point format is 7.2, which represents that the bit number of the effective data is 7, the bit number of the decimal part is 2, and the TW of the data represented by the predetermined fixed-point format is 8. The output feature value output by the computation circuit 320 may be 16′b0000_0011_1111_1010 (“16” represents the TW of the output feature value, and “b” represents binary), the fixed-point formation of the output feature value may be 15.4 (i.e., the bit number of the effective data is 15, and the bit number of the decimal part is 4).

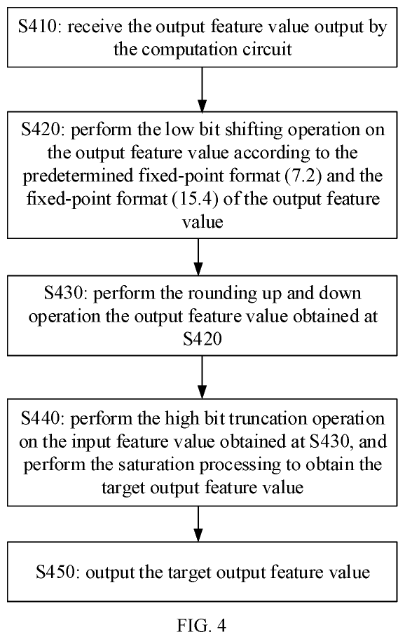

FIG. 4 is a schematic flowchart showing the output circuit processing an output feature value.

At S410, the output feature value output by the computation circuit 320 is received.

At S420, the low bit shifting operation is performed on the output feature value according to the predetermined fixed-point format (7.2) and the fixed-point format (15.4) of the output feature value.

In some embodiments, the bit number of the low bits of the output feature value, which needs to be shifted out, is 2. The bits shifted out is “10.” After the low bit shifting operation, the output feature value is 16′b0000_0000_1111_1110.

At S430, the rounding up and down operation is performed on the output feature value obtained at S420.

In some embodiments, the largest value that two bits may represent is “11,” which is 3 in decimal system. The binary bits shifted out at S420 is “10,” which is 2 in decimal system. Since the bit value “10” shifted out is larger than half of the largest value that can be represented by the binary bit number shifted out, the output feature value 16′b0000_0000_1111_1110, which is obtained at S430, is added by 1 to obtain 16′b0000_0000_1111_1111. That is, the smallest value that can be represented by three binary bits that is larger than the largest value that can be represented by two binary bits is “100,” which is 4 in decimal system. The binary bits shifted out at S420 is “10,” which is 2 in decimal system, and hence the rounding up operation is performed.

In some embodiments, since the two bits “10” of the decimal bit number are removed, the method of converting binary to decimal may be performed, for example, x=1*2⁻³+0*2⁻⁴=0.125, where −3 and −4 represent a third and fourth bits of the decimal bits. The smallest value that can be represented by three binary bits that is greater than the largest value that can be represented by two binary bits is “100,” and hence the decimal value is x=1*2⁻²+0*2⁻³+0*2⁻⁴=0.25. Since 0.125 is half of 0.25, the rounding up operation may be performed.

At S440, the high bit truncation operation is performed on the input feature value obtained at S430, and the saturation processing is performed to obtain the target output feature value.

Since the predetermined fixed-point format is 7.2, the high bit truncation operation may need to be performed on the output feature value 16′b0000_0000_1111_1111 obtained at S430, and the result obtained may be “1111_1111.” This result exceeds the largest value 8′b 0111_1111 (“8” represents the TW of 8, and “b” represents binary) represented by 8 bits. Therefore, the saturation processing may need to be performed on the result, that is, the largest positive value 8′b0111_1111 represented by eight bits may be used as the final output feature value, i.e., the targe output feature value may be 8′b0111_1111.

At S450, the target output feature value (i.e., 8′b0111_1111) is output.

The process at S430 may cause the final output feature value to have a small accuracy loss. The saturation processing at S440 may ensure the accuracy and effectiveness of the final output feature value.

FIG. 4 is only exemplary and is not a limitation, and embodiments of the present disclosure are not limited here. For example, if the decimal bit number represented by the fixed-point format of the output feature value output by the computation circuit 320 is equal to the bit number represented by the predetermined fixed-point format, processes S420 and S430 may not need to be performed, after process S410, process S440 may be directly performed. As another example, if at S440, the result after the high bit truncation operation does not exceed the largest value represented by the predetermined fixed-point format, the saturation processing may not need to be performed. As another example, if the bit number of the effective data represented by the fixed-point format of the output feature value output by the computation circuit 320 is equal to the bit number of the effective data represented by the predetermined fixed-point format, the high bit truncation operation at S440 may not need to be performed.

Assume that the fixed-point format of the output feature value output by the computation circuit 320 is the same as the predetermined fixed-point format, the output circuit 320 may not need to process the output feature value, which may be directly output.

In above embodiments, processing manners of the output circuit 330 performed on the output feature value output by the computation circuit 320 may be adaptively applied individually or in combination according to actual needs in practical applications. These solutions are all within the scope of the present disclosure.

As described above, the fixed-point format of the input feature value after the fixed-point conversion may be different from the data format required by the computation circuit of the neural network acceleration device. For example, the fixed-point format of the input feature value may be 7.2 (the bit number of the effective number is 7 and the bit number of the decimal is 2), and the bit-width of the input and output required by the computation circuit may be 16 bits. In this scenario, the input circuit 310 may need to perform corresponding processing on the obtained input feature value to cause the data input to the computation circuit 320 to match the data format required by the computation circuit 320. In addition, to reduce the accuracy loss, the bit-width extension operation may need to be performed on the data between the computation processing. In addition, if the fixed-point formats of a plurality of input feature values are different, the shifting operation may need to be performed on the plurality of input feature values. For example, the shifting operation may be performed according to the fixed-point format of the input feature value having the most decimal bit number.

In some embodiments, the input circuit 310 may be configured to perform the bit-width extension operation on the obtained input feature value. The computation circuit 320 may be configured to perform the computation processing on the input feature value after the bit-width extension operation to obtain the output feature value.

For example, the input circuit 310 may perform the bit-width extension operation on the input feature value according to the input bit-width required by the computation circuit 320, such that the TW of the input feature value after the bit-width extension operation may be the same as the input bit-width required by the computation circuit 320.

For example, when the TW of the input feature value is smaller than the input bit-width required by the computation circuit 310, the bit-width extension may be performed on the input feature value, and the length of the bit-width extension may be a positive number larger than 0. As another example, when the TW of the input feature value is equal to the input bit-width required by the computation circuit 310, the bit-width extension may not need to be performed on the input feature value, or in other words, the length of the bit-width extension may be 0.

When the decimal bit number represented by the fixed-point format of the input feature value is deferent from the decimal bit number represented by the fixed-point format required by the computation circuit 310, while the bit-width extension operation is performed on the input feature value, the shifting operation may also need to be performed on the input feature value.

In some embodiments, the input circuit 310 may be configured to obtain at least two input feature values, and the at least two input feature values have different fixed-point formats. The input circuit 310 may be configured to perform the bit-width extension operation and the shifting operation on the at least two input feature values. The computation circuit 320 may be configured to perform the computation processing on the input feature value after the bit-width extension operation and the shifting operation to obtain the output feature value.

In some embodiments, the at least two feature values may have different fixed-point formats, which may include different TWs corresponding to the fixed-point formats of the at least two input feature values and/or different decimal bit numbers corresponding to the fixed-point formats of the at least two input feature values.

For example, the TWs corresponding to the fixed-point formats of the at least two input feature values may be different, and the decimal bit numbers corresponding to the fixed-point formats of the at least two input feature values may be the same. Thus, the input circuit 310 may need to perform the bit-width extension operation on the at least two input feature values to cause the TWs of the at least two input feature values after the processing to be the same. The bit-width extension operation may be performed on the at least two input feature values with reference to the input bit-width required by the computation circuit 320.

As another example, the TWs corresponding to the fixed-point formats of the at least two input feature values may be the same, and the decimal bit numbers corresponding to the fixed-point formats of the at least two input feature values may be different. Thus, the input circuit 310 may perform the bit-width extension operation on the at least two input feature values according to the input bit-width required by the computation circuit 320, such that the TWs of the at least two input feature values after the bit-width extension operation may be the same as the input bit-width required by the computation circuit 320. Then, the shifting operation may need to be performed on the at least two input feature values. In some embodiments, a right shifting operation (e.g., add 0 to the low bit) may be performed on the input feature value having fewer decimal bits to finally cause the decimal points of the at least two input feature values to be aligned.

As another example, the TWs corresponding to the fixed-point formats of the at least two input feature values may be different, and the decimal bit numbers corresponding to the fixed-point formats of the at least two input feature values may be different. Thus, the input circuit 310 may perform the bit-width extension operation on the at least two input feature values according to the input bit-width required by the computation circuit 320, such that the TWs of the at least two input feature values after the bit-width extension operation may be the same as the input bit-width required by the computation circuit 320. Then, the shifting operation may need to be performed on the at least two input feature values. In some embodiments, the right shifting operation (e.g., add 0 to the low bits) may be performed on the input feature value having fewer decimal bits to finally cause the decimal points of the at least two input feature values to be aligned.

The neural network acceleration device provided by embodiments of the present disclosure may perform the adjustment on the fixed-point format of the input feature value according to the fixed-point format required by the computation circuit to cause the fixed-point format of the input feature value after the adjustment to be the same as the fixed-point format required by the computation circuit. Compared to the existing technology, the solution provided by embodiments of the present disclosure may not need the CPU to perform the adjustment operation on the fixed-point format of the input feature value. As such, the number of the data exchanges performed by the neural network acceleration device via the DDR and the CPU may be reduced. On one aspect, the data processing efficiency may be improved. On another aspect, the usage of the DDR may be reduced.

When the fixed-point format of the input feature value obtained by the input circuit 310 is the same as the fixed-point format required by the computation circuit 320, the input circuit 310 may not need to process the input feature value, which may be directly transmitted to the computation circuit 320 for computation.

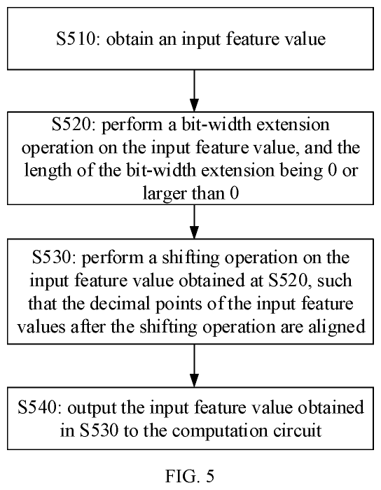

FIG. 5 is a schematic flowchart showing the input circuit of the neural network acceleration device processing the input feature value according to some embodiments of the present disclosure. As shown in FIG. 5. The processing method includes the following processes.

At S510, an input feature value is obtained.

At S520, a bit-width extension operation is performed on the input feature value, and the length of the bit-width extension may be 0 or larger than 0.

As an example, the length of the bit-width extension performed on the input feature value may be determined according to the input bit-width required by the computation circuit 310. For example, when the TW represented by the fixed-point format of the input feature value is equal to the input bit-width required by the computation circuit 310, the bit-width extension may not need to be performed on the input feature value, or the length of the bit-width extension may be zero. As another example, when the TW represented by the fixed-point format of the input feature value is smaller than the input bit-width required by the computation circuit 310, the bit-width extension operation may need to be performed on the input feature value, and the length of the bit-width extension may be a positive number larger than zero.

In some embodiments, the length of the bit-width extension required for the input feature value may be configured by a configuration program via a register.

At S530, a shifting operation is performed on the input feature value obtained at S520, such that the decimal points of the input feature values after the shifting operation are aligned.

In some embodiments, the input circuit 310 may obtain at least two input feature values, and the decimal bit numbers corresponding to the fixed-point formats of the at least two input feature values may be different. In this scenario, based on the input feature value having the most decimal bits of the at least two input feature values the right shifting operation (i.e., add a 0 to the low bit) may be performed on other input feature values.

At S540, the input feature value obtained in S530 is output to the computation circuit 310.

The input circuit 320 may process a plurality of input feature values simultaneously, which may not be limited by embodiments of the present disclosure.

To better understand the solution of the present disclosure, based on an example below, the data processing flow of the neural network acceleration device 300 provided by the present disclosure is described. The fixed-point format in the example represents the fixed-point number having the sign bit.

An assumption is made to the neural network acceleration device 300 as follows. The bit-width of an input of the input circuit 310 of the neural network acceleration device 300 may include 8 bits, that is, the bit-width of the input feature value obtained by the input circuit 310 may be 8 bits. Each bit-width of the input and output of the computation circuit 320 in the neural network acceleration device 300 may be 16 bits, that is, the TW corresponding to the data format required by the computation circuit 320 may be 16 bits. The computation circuit 320 may complete the operation of C=A+B for the input feature value A and the input feature value B to obtain the output feature value C. The output feature value C may be output to the output circuit 330. The output circuit 330 may process the output feature value C according to the predetermined fixed-point format, such that the fixed-point format of the final output feature value may be the same as the predetermined fixed-point format.

An assumption may be made to the input feature value A and the input feature value B as follows.

The bit-width of the input feature value A may be 8 bits, the input feature value may be 8′b0111_0010, and the fixed-point format may be 7.2 (i.e., the bit number of the effective data is 7, and the decimal bit number of the effective data is 2).

The bit-width of the input feature value B may be 8 bits, the input feature value may be 8′b0011_0010, and the fixed-point format may be 7.4 (i.e., the bit number of the effective data is 7, and the decimal bit number of the effective data is 4).

The input circuit 310 may obtain the input feature value A and the input feature value B and perform the bit-width extension operation and the shifting operation on the input feature value A and the input feature value B.

For example, to not lose the data accuracy of the input feature values A and B, the input circuit 310 may extend the feature values A and B to 16 bits, and the fixed-point format may be 15.4. The input feature value A may become 16′b0000_0000_0111_0010 after the bit-width extension operation, and the input feature value B may become 16′b0000_0000_0011_0010 after the bit-width extension operation.

Assume that a configuration value of the input circuit 310 may represent a bit number that the input feature value is shifted to the left. Thus, the configuration value applied may be 2 when the input circuit 310 processes the input feature value A, that is, the input feature value A may be shifted by two bits (i.e., add two 0 s to the low bits) to the left. The configuration value may be 0 when the input circuit 310 processes the feature value B, that is, the shifting operation may not be performed on the input feature value B, or the shifting length may be 0.

Therefore, according to the fixed-point format 15.4, after the bit-width extension operation and the shifting operation, the input feature value A may become 16′b0000_0001_1100_1000. After the bit-width extension operation and the shifting operation (the shifting length is zero), the input feature value B may become 16′b0000_0000_0011_0010.

The input circuit 310 may transmit the input feature value A and the input feature value B obtained after the above-described processes to the processing circuit 320.

The processing circuit 320 may perform the following computation C=A+B on the received input feature value A and the input feature value B to obtain the output feature value C, i.e., 16′b0000_0001_1111_1010. The processing circuit 320 may transmit the output feature value C to the output circuit 330 for processing.

For example, the output circuit 330 may process the output feature value C according to the predetermined fixed-point format 7.2.

The fixed-point format of the output feature value C received by the output circuit 330 from the computation circuit 320 may be 15.4. The output feature value C may be processed to be converted to a data of the fixed-point format 7.2. First, the shifting operation may be performed on the output feature value C. In some embodiments, a right shifting operation (i.e., the low bits are shifted out) may be performed. For example, the configuration value of the output circuit 330 may represent the bit number that the output feature value may be shifted to the right. Thus, the configuration value may be 2 when the output circuit 330 processes the output feature value C.

After being shifted two bits to the right (i.e., two low bits are shifted out), the output feature value C may become 16′b0000_0000_0111_1110.

Then, the rounding up and down operation may be performed on the output feature value C after the low bit shifting operation. Since the output feature value C may be a positive number, and the data shifted out may be 2′b10, which is larger than half of the largest value that can be represented by two bits, the output feature value C after the low bit shifting operation may be added by 1. The output feature value C may become 16′b0000_0000_0111_1111.

Since the predetermined fixed-point format may be 7.2, the high bit truncation operation may need to be performed on the output feature value C to cause the TW to become 8. After the high bit truncation operation, the output feature value C may become 8′b0111_1111. In other words, the final output feature value C output by the output circuit 330 may be 8′b0111_1111.

Assume that the input feature value A and the input feature value B obtained by the input circuit 310 may have other values, and after the computation circuit 320 performs the computation C=A+B on the input feature value A and the input feature value B, the obtained output feature value C may be 16′b0000_0011_1111_1010. Assume that the predetermined fixed-point format may still be 7.2, thus the output feature value C may become 8′b1111_1111 after the output circuit 330 performs the shifting operation and the high bit truncation operation on the output feature value C. Since the value exceeds the largest integer 8′b0111_1111 that 8 bits can represent, the saturation processing may need to be performed on the input feature value C, that is, the largest integer 8′b0111_1111 that the 8 bits can represent may be used as the final output feature value C.

In summary, in some embodiments, the fixed-point format of the data may be adjusted by the neural network acceleration device. Since the CPU may not be needed to perform the adjustment on the fixed-point format of the data, the usage of the DDR may be reduced to a certain degree, and the resource consumption may be reduced.

The neural network acceleration device provided by embodiments of the present disclosure may be integrated at a chip.

Device embodiments of the present disclosure are described above, and method embodiments of the present disclosure are described below. Method embodiments correspond to the above-described device embodiments. The solution description and the technical effect description in device embodiments may be applicable to method embodiments below.

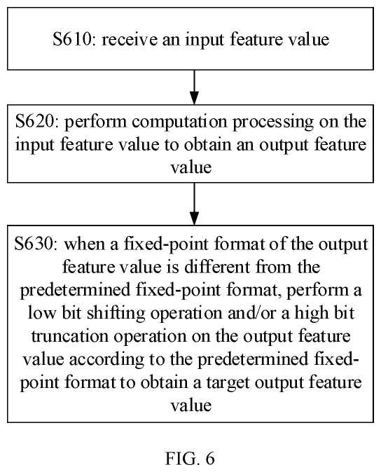

FIG. 6 is a schematic flowchart showing a data processing method 600 used in the neural network according to some embodiments of the present disclosure. The method 600 may be executed by the neural network acceleration device 300 of embodiments of the present disclosure. The method 600 includes the following processes.

At S610, an input feature value is received.

At S620, computation processing is performed on the input feature value to obtain an output feature value.

At S630, when a fixed-point format of the output feature value is different from the predetermined fixed-point format, a low bit shifting operation and/or a high bit truncation operation are performed on the output feature value according to the predetermined fixed-point format to obtain a target output feature value. The fixed-point format of the target output feature value is the predetermined fixed-point format.

In the solution of embodiments of the present disclosure, the fixed-point format of the data may be adjusted by the neural network acceleration device. Since the CPU may not be needed to perform the adjustment on the fixed-point format of the data, the usage of the DDR may be reduced to a certain degree, and the resource consumption may be reduced.

In some embodiments, obtaining the target output feature value includes shifting out the L1 low bits of the output feature value according to the predetermined fixed-point format. L1 is a positive integer. The value represented by the L1 low bits may be larger than or equal to half of the largest value that can be represented by L1 bits. Obtaining the target output feature value may further include adding 1 to the output feature value that the L1 low bits are shifted out to obtain the target output feature value.

In some embodiments, obtaining the target output feature value further may further include shifting out L2 low bits of the output feature value according to the predetermined fixed-point format. L2 may be a positive integer. The value represented by the L2 low bits may be smaller than half of the largest value that can be represented by L2 bits. Obtaining the target output feature value may further include using the output feature value that the L2 low bits are shifted out as the target output feature value.

In some embodiments, the value of the output feature value may be larger than the largest value represented by the predetermined fixed-point format. Obtaining the target output feature value may further include using the largest value represented by the predetermined fixed-point format as the target output feature value.

In some embodiments, the predetermined fixed-point format may represent that the bit number of the effective data of the fixed-point number having the sign bit may be mi, and the bit number of the decimal of the effective data may be ni. The target output feature value may be larger than the largest value that can be represented by m₁+1 bits. Obtaining the target output feature value may further include using the positive largest value that can be represented by m₁+1 bits as the target output feature value.

In some embodiments, the output feature value may be larger than the smallest value represented by the predetermined fixed-point format. Obtaining the target output feature value may further include using the smallest value represented by the predetermined fixed-point format as the target output feature value.

In some embodiments, the predetermined fixed-point format may represent that the bit number of the effective data of the fixed-point number having the sign bit may be m₂, and the bit number of the decimal of the effective data may be n₂. The target output feature value may be smaller than the smallest value that can be represented by m₂+1 bits. Obtaining the target output feature value may further include using the negative smallest value that can be represented by m₂+1 bits as the target output feature value.

In some embodiments, the method 600 may further include performing the bit-width extension operation on the input feature value. Performing the computation processing on the input feature value may include performing the computation processing on the input feature value after the bit-width extension operation to obtain the output feature value.

In some embodiments, receiving the input feature value may include receiving at least two input feature values. The at least two input feature values may have different fixed-point formats. The method may further include performing the bit-width extension operation on the at least two input feature values and performing the shifting operation on the at least two feature values after the bit-width extension operation. The at least two input feature values after the shifting operation may have the same fixed-point format. Performing the computation processing on the input feature value may include performing the computation processing on the at least two input values after the shifting operation to obtain the output feature value.

In some embodiments, performing the computation processing on the input feature value may further include performing any one of the following computation processes, such as a convolutional computation or a pooling computation.

Embodiments of the present disclosure may further provide a computer-readable storage medium. The computer-readable storage medium may store a computer program that, when executed by a computer or processor, may cause the computer or processor to perform a method consistent with the disclosure, such as one of the example methods described above.

Embodiments of the present disclosure may further provide a computer program product containing instructions. The instructions, when executed by a computer or processor, may cause the computer or processor to perform a method consistent with the disclosure, such as one of the example methods described above.

Embodiments of the present disclosure may be implemented in whole or in part by software, hardware, firmware, or any other combinations. When implemented by software, embodiments of the present disclosure may be implemented in the form of a computer program product in whole or in part. The computer program product includes one or more computer instructions. When the computer program instructions are loaded and executed on a computer, all or part of the processes or functions described in embodiments of the present disclosure are generated. The computer may be a general-purpose computer, a special-purpose computer, a computer network, or other programmable devices. The computer instructions may be stored in a computer-readable storage medium or transmitted from one computer-readable storage medium to another computer-readable storage medium. For example, the computer instructions may be transmitted from a website, computer, server, or data center to another website, computer, server, or data center via wired (such as a coaxial cable, an optical fiber, a digital subscriber line (DSL)) or wireless (such as infrared, wireless, microwave, etc.). The computer-readable storage medium may be any available medium that can be accessed by a computer or a data storage device such as a server or data center integrated with one or more available media. The usable medium may include a magnetic medium (for example, a floppy disk, a hard disk, a magnetic tape), an optical medium (for example, a digital video disc (DVD)), or a semiconductor medium (for example, a solid-state disk (SSD)), etc.

Those of ordinary skill in the art may be aware that the units and algorithm steps of the examples described in embodiments of the present disclosure may be implemented by electronic hardware or a combination of computer software and electronic hardware. Whether these functions are executed by hardware or software depends on the application and design constraint conditions of the technical solution. Those skilled in the art may use different methods for each application to implement the described functions, but such implementation should not be considered beyond the scope of the present disclosure.

In embodiments of the present disclosure, the disclosed system, device, and method may be implemented in other ways. For example, the device embodiments described above are only illustrative. For example, the division of the units is only a logical functional division, and other divisions may exist in actual implementation, for example, multiple units or components can be combined or integrated into another system, or some features can be ignored or not implemented. In addition, the displayed or discussed mutual coupling or direct coupling or communication connection may be indirect coupling or communication connection through some interfaces, devices, or units, and may be in electrical, mechanical, or other forms.

The units described as separate components may or may not be physically separated, and the components displayed as units may or may not be physical units, that is, they may be located in one place, or they may be distributed on multiple network units. Some or all of the units can be selected according to actual needs to achieve the purpose of the solution of embodiments of the present disclosure.

In addition, the functional units in each embodiment of the present application may be integrated into one processing unit, or each unit may exist alone physically, or two or more units may be integrated into one unit.

Embodiments of the present disclosure are merely example embodiments of the present disclosure, but the scope of the present disclosure is not limited to this. Anyone skilled in the art can easily think of changes or substitutions within the technical scope disclosed in the present disclosure, which are within the scope of the present disclosure. Therefore, the scope of the present invention should be subject to the scope of the claims.

What is claimed is:

1. A neural network acceleration device comprising:
a processor; and
a storage medium storing instructions that, when executed by the processor, cause the processor to:
obtain an input feature value;
perform computation processing on the input feature value to obtain an output feature value; and
in response to a fixed-point format of the output feature value being different from a predetermined fixed-point format, perform at least one of a low bit shifting operation or a high bit truncation operation on the output feature value according to the predetermined fixed-point format to obtain a target output feature value, a fixed-point format of the target output feature value being the predetermined fixed-point format.

2. The device of claim 1, wherein the instructions further cause the processor to:
shift out L1 low bits of the output feature value according to the predetermined fixed-point format to obtain a processed output feature value, L1 being a positive integer, and the L1 low bits representing a value larger than half of a largest value represented by L1 bits; and
add 1 to the processed output feature value to obtain the target output feature value.

3. The device of claim 1, wherein the instructions further cause the processor to:
shift out L2 low bits of the output feature value according to the predetermined fixed-point format to obtain a processed output feature value, L2 being a positive integer, and the L2 low bits representing a value smaller than half of a largest value represented by L2 bits; and
output the processed output feature value as the target output feature value.

4. The device of claim 1, wherein:
the output feature value is larger than a largest value represented by the predetermined fixed-point format; and
the instructions further cause the processor to output the largest value represented by the predetermined fixed-point format as the target output feature value.

5. The device of claim 4, wherein:
the predetermined fixed-point format represents that a bit number of effective data of a fixed-point number having a sign bit is m₁, and a bit number of a decimal part of the effective data is m;
the target output feature value is larger than a largest positive value represented by m₁+1 bits; and
the instructions further cause the processor to output the largest positive value represented by the m₁+1 bits as the target output feature value.

6. The device of claim 1, wherein:
the output feature value is larger than a smallest value represented by the predetermined fixed-point format; and
the instructions further cause the processor to output the smallest value represented by the predetermined fixed-point format as the target output feature value.

7. The device of claim 6, wherein:
the predetermined fixed-point format represents that a bit number of effective data of a fixed-point number having a sign bit is m₂, a bit number of a decimal part of the effective data is n₂;
the target output feature value is smaller than a smallest negative value represented by m₂+1 bits; and
the instructions further cause the processor to output the smallest negative value represented by the m₂+1 bits as the target output feature value.

8. The device of claim 1, wherein the instructions further cause the processor to:
perform a bit-width extension operation on the input feature value; and
perform the computation processing on the input feature value after the bit-width extension operation to obtain the output feature value.

9. The device of claim 1, wherein:
the input feature value is one of at least two input feature values having different fixed-point formats; and
the instructions further cause the processor to:
obtain the at least two input feature values;
perform a bit-width extension operation on the at least two input feature values;
perform a shifting operation on the at least two input feature values after the bit-width extension operation, the at least two input feature values after the shifting operation having a same fixed-point format; and
perform the computation processing on the at least two input feature values after the shifting operation to obtain the target output feature value.

10. The device of claim 1, wherein the instructions further cause the processor to perform at least one of a convolutional computation or a pooling computation on the input feature value.

11. A neural network data processing method comprising:
obtaining an input feature value;
performing computation processing on the input feature value to obtain an output feature value; and
in response to a fixed-point format of the output feature value being different from a predetermined fixed-point format, performing at least one of a low bit shifting operation or a high bit truncation operation on the output feature value according to the predetermined fixed-point format to obtain a target output feature value, a fixed-point format of the target output feature value being the predetermined fixed-point format.

12. The method of claim 11, wherein obtaining the target output feature value includes:
shifting out L1 low bits of the output feature value according to the predetermined fixed-point format to obtain a processed output feature value, L1 being a positive integer, and the L1 low bits representing a value larger than half of a largest value represented by L1 bits; and
adding 1 to the processed output feature value to obtain the target output feature value.

13. The method of claim 11, wherein obtaining the target output feature value further includes:
shifting out L2 low bits of the output feature value according to the predetermined fixed-point format to obtain a processed output feature value, L2 being a positive integer, and the L2 low bits representing a value smaller than half of a largest value represented by L2 bits; and
outputting the processed output feature value as the target output feature value.

14. The method of claim 11, wherein:
the output feature value is larger than a largest value represented by the predetermined fixed-point format; and
obtaining the target output feature value further includes outputting the largest value represented by the predetermined fixed-point format as the target output feature value.

15. The method of claim 14, wherein:
the predetermined fixed-point format represents that a bit number of effective data of a fixed-point number having a sign bit is m₁, and a bit number of a decimal part of the effective data is n₁;
the target output feature value is larger than a largest positive value represented by m₁+1 bits; and
obtaining the target output feature value further includes outputting the largest positive value represented by the m₁+1 bits as the target output feature value.

16. The method of claim 11, wherein:
the output feature value is larger than a smallest value represented by the predetermined fixed-point format; and
obtaining the target output feature value further includes outputting the smallest value represented by the predetermined fixed-point format as the target output feature value.

17. The method of claim 16, wherein:
the predetermined fixed-point format represents that a bit number of effective data of a fixed-point number having a sign bit is m₂, a bit number of a decimal part of the effective data is n₂;
the target output feature value is smaller than a smallest negative value represented by m₂+1 bits; and
obtaining the target output feature value further includes outputting the smallest negative value represented by the m₂+1 bits as the target output feature value.

18. The method of claim 11, further comprising:
performing a bit-width extension operation on the input feature value; and
performing the computation processing on the input feature value after the bit-width extension operation to obtain the output feature value.

19. The method of claim 11,
wherein the input feature value is one of at least two input feature values having different fixed-point formats;
further comprising:
obtaining the at least two input feature values;
performing a bit-width extension operation on the at least two input feature values;
performing a shifting operation on the at least two input feature values after the bit-width extension operation, the at least two input feature values after the shifting operation having a same fixed-point format; and
performing the computation processing on the at least two input feature values after the shifting operation to obtain the target output feature value.

20. The method of claim 11, wherein performing the computation processing on the input feature value includes:
performing at least one of a convolutional computation or a pooling computation on the input feature value.
